(19) United States
(12) Patent Application Publication
(10) Pub. No.: US 2023/0155526 A1
(43) Pub. Date: May 18, 2023

(54) SUBSAMPLING ACTIVE GATE DRIVER FEEDBACK

(71) Applicant: Kabushiki Kaisha Toshiba, Tokyo (JP)

(72) Inventor: Gavin Tomas WATKINS, Bristol (GB)

(73) Assignee: Kabushiki Kaisha Toshiba, Tokyo (JP)

(21) Appl. No.: 17/526,595

(22) Filed: Nov. 15, 2021

(51) Int. Cl. H02P 7/29; H02P 29/50; H03H 21/00

(52) U.S. Cl. CPC H02P 7/29; H02P 29/50; H03H 21/0043

(57) ABSTRACT

An embodiment provides a closed loop active gate driver configured to drive a switch for an inductive load and including a feedback loop, the feedback loop configured to sample a repetitive output waveform of the inductive load, the output waveform having a plurality of repetitive cycles and the feedback loop configured to sample the output waveform using a sampling rate that is lower than a sampling rate required for characterizing the output waveform, sample points acquired in cycles of the plurality of cycles are acquired at different time points during the cycles and wherein a representation of the output waveform is reconstructed using the sample points.

### FIELD

Embodiments described herein generally relate to active gate drivers and more specifically to ways of creating a representation of an output waveform of an apparatus driven by an active gate driver.

### BACKGROUND

Brushless DC (BLDC) or “digital” motors have been widely adopted for many applications like electric vehicles, industrial cooling and consumer electronics. In this configuration, the magnets are placed on the rotor and coils on the stator. The coils are synchronously driven with pulsed waveforms to move the rotor. To maximize efficiency the coils are driven with fast-pulsed waveforms to fully energized or switched off the coils. This can produce ringing on the current and voltage waveform, particularly with modern fast switching devices (transistors) like Silicon Carbide (SiC) and Gallium nitride (GaN). The ringing can cause excess device stresses leading to device failure and may further have very high frequency content, e.g. up to hundreds of megahertz, that causes interference which can exceed electromagnetic compatibility (EMC) regulations.

Arrangements of embodiments will be understood and appreciated more fully from the following detailed description, made by way of example only and taken in conjunction with drawings in which:

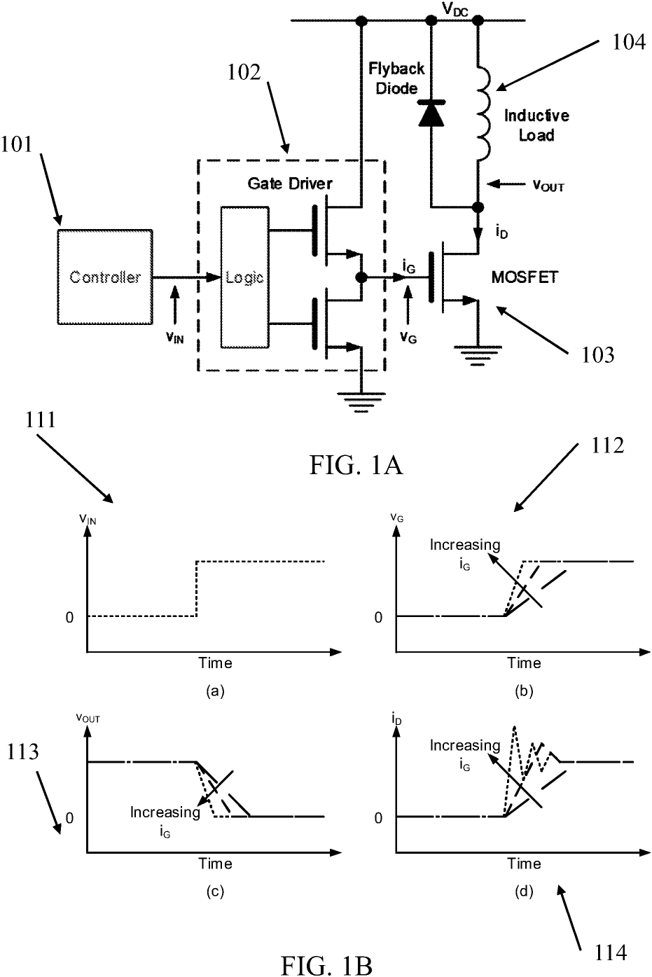

FIG. 1A shows a known gate driver circuit;

FIG. 1B shows current and voltage waveforms for the prior art gate driver of FIG. 1A;

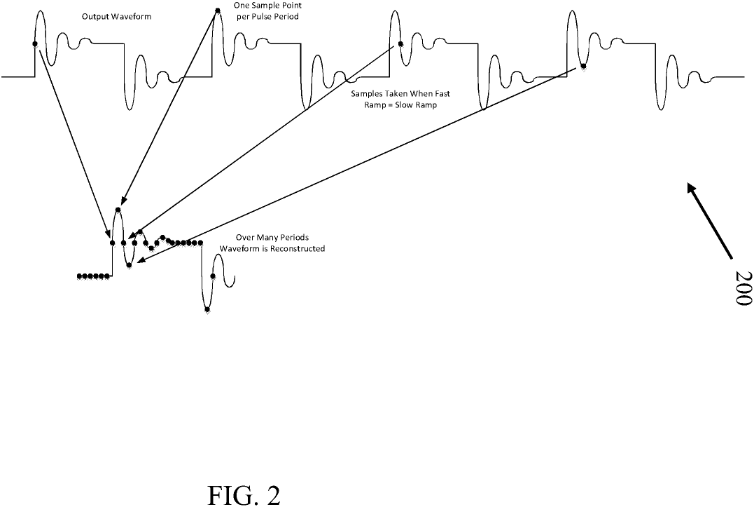

FIG. 2 shows a sub-sampling scheme of an embodiment;

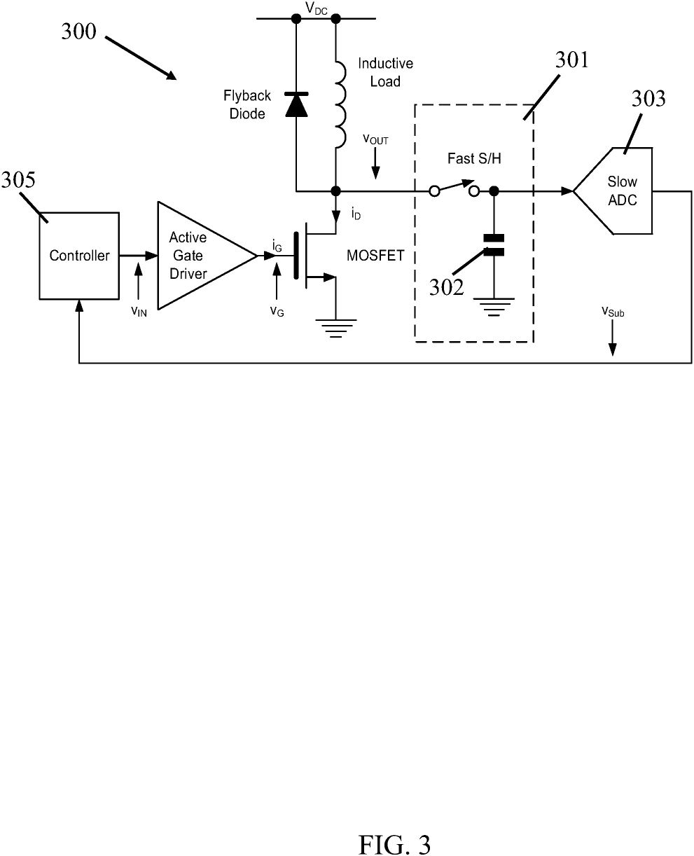

FIG. 3 shows an active gate driver system using a feedback loop of an embodiment;

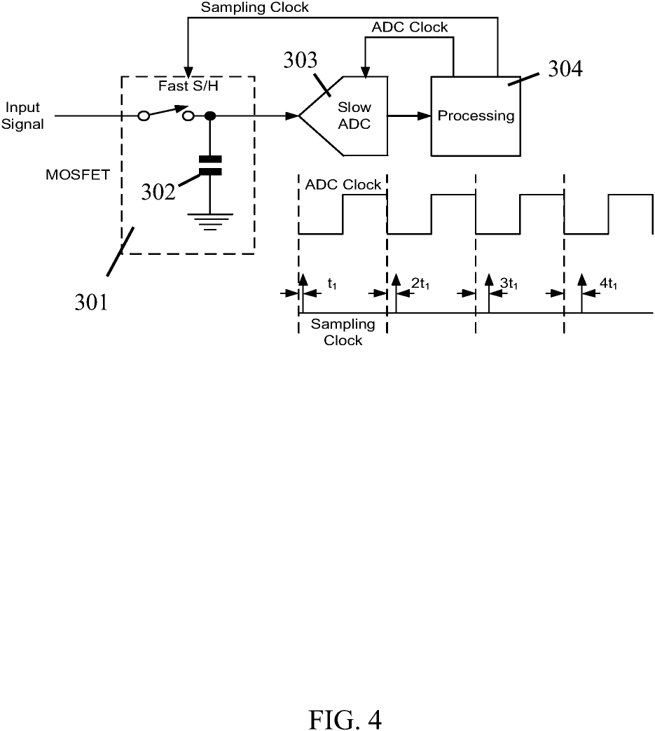

FIG. 4 shows details of the circuit shown in FIG. 3; and

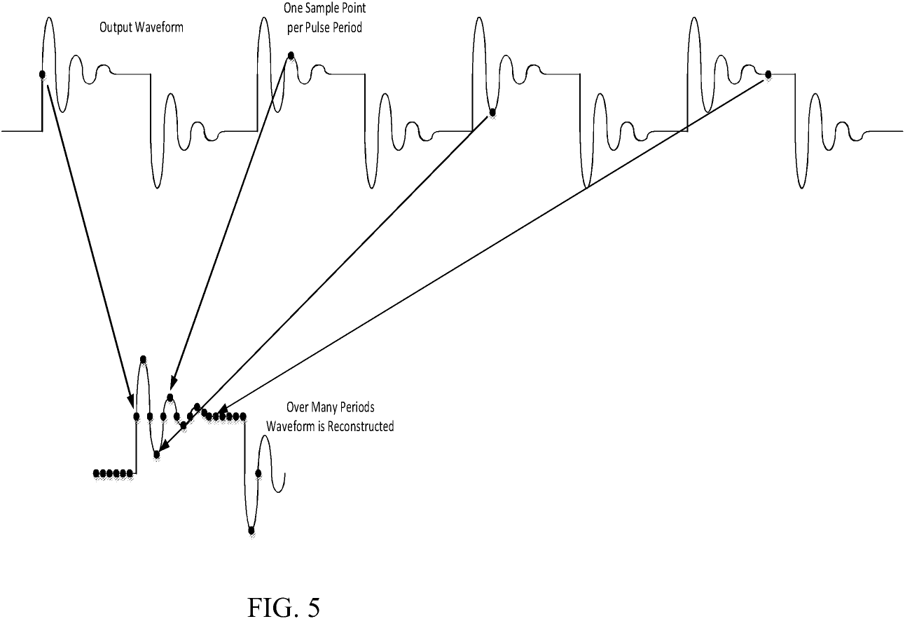

FIG. 5 shows a sub-sampling scheme of another embodiment.

### DETAILED DESCRIPTION

According to a first aspect there is provided a closed loop active gate driver configured to drive a switch for an inductive load and comprising a feedback loop. The feedback loop is configured to sample an output waveform of the inductive load. The output waveform has a plurality of repetitive cycles. The feedback loop is configured to sample the output waveform using a sampling rate that is lower than a sampling rate required for characterizing an individual cycle of the output waveform. Sample points acquired in cycles of the plurality of cycles are acquired at different time points during the cycles. A representation of the output waveform is reconstructed using the sample points.

In an embodiment, the active gate driver is configured to pre-distort a driving signal applied to the switch using the representation of the output waveform, so that the shape of the sampled output waveform corresponds to a desired waveform shape.

In an embodiment, a sampled characteristic of the output waveforms is at least one of a voltage or a current of the output waveform.

In an embodiment the feedback loop comprises a sample and hold circuit and the active gate driver further comprises a controller configured to control the sample and hold circuit such that the sample and hold circuit acquires the sample points at the different time points during the cycles and such that a sample period during which the sample and hold circuit samples the output waveform is of a duration that enables the reconstruction of the output waveform using the sample points.

In an embodiment, the sample period is of a duration over which a sampled characteristic of the output waveform remains substantially unchanged.

In an embodiment, the sample period is 1 ns or less.

In an embodiment, each sample point of the sample points is offset from a start point of a cycle of the plurality of cycles in which the sample point is acquired and where the offset increases from cycle to cycle.

In an embodiment, the offset for a next cycle is set to zero if an increase of an offset used in a current cycle is longer than a known or estimated length of the waveform cycle.

In an embodiment, each sample point of the sample points is offset from a start point of a cycle of the plurality of cycles in which the sample point is acquired. In the embodiment, the offset is random over the cycles.

In an embodiment, the switch is a GaN transistor or a SiC Metal Oxide Semiconductor Field Effect Transistor (MOSFET).

In an embodiment, the closed loop active gate driver further comprises a further switch driven by a further active gate driver, wherein the feedback loop is configured to provide feedback to the active gate driver and to the further active gate driver.

In an embodiment the closed loop active gate driver further comprises at least one of a microprocessor or a field programmable gate array, the at least one microprocessor or field programmable gate array configured to reconstruct said output waveform.

In an embodiment, the feedback loop comprises a low-speed ADC.

In an embodiment the low-speed, ADC has a sampling speed of less than 1 MSps.

In another embodiment there is provided a system comprising a motor and an active gate as described above. In the embodiment, the inductive load is at last one winding of the motor and the feedback loop is configured to sample said output waveform at the at least one winding.

In an embodiment, the motor is a brushless DC motor.

In another embodiment there is provided a method of obtaining a representation of an output waveform of an inductive load driven by a switch. The output waveform has a plurality of repetitive cycles. The method comprises sampling each cycle of the plurality of repetitive cycles using a sampling rate that is lower than a sampling rate required for characterizing the cycle. Sample points acquired in cycles of the plurality of cycles are acquired at different time points during the cycles. A representation of the output waveform is reconstructed using the sample points.

In an embodiment, the representation of the output waveform is provided to an active gate driver connected to the switch.

FIG. 1A shows a known gate driver circuit. FIG. 1A shows a gate driver circuit comprising a controller 101, a gate driver 102, an electronic switch 103 and an inductive load 104. In FIG. 1A, the electronic switch 103 is a Metal Oxide Semiconductor Field Effect Transistor (MOSFET) and the inductive load 104 represents a motor winding of a Brushless DC motor. In FIG. 1A the gate voltage to the electronic switch, v_{G}, is supplied by two smaller MOSFETs in the gate driver 102 and can vary between ground and the supply voltage, V_{DC}. When the gate voltage, v_{G}, reaches a certain threshold the electronic switch 103 turns on causing a large drain current, i_{D}, to flow and the output voltage, v_{OUT}, to drop. Likewise, when the gate voltage, v_{G}, drops below the threshold the electronic switch 103 will turn off.

FIG. 1B shows current and voltage waveforms for the prior art gate driver of FIG. 1A. A first plot 111 of FIG. 1B shows the voltage at the input to the gate driver 102, v_{IN}, changing over time as a step-function input signal is outputted by the controller 101. This signal is then transformed by the gate driver 102 into a signal suitable for driving the gate of the MOSFET. The electronic switch 103 will typically be a physically large device and will possess a large capacitance, for example 100 pF to 1 nF, between its gate and its source, C_{GS}. Due to the large gate-source capacitance, C_{GS}, of the electronic switch 103 it will take a finite amount of time for the gate voltage of the electronic switch 103, v_{G}, to respond to the input signal. The amount of time depends on the available gate current, i_{G}, which is often limited by the gate driver 102. This effect can be seen from a second plot 112 that shows the rise time of the gate voltage, v_{G}, decreasing as the available gate current, i_{G}, increases. Accordingly, this has the effect of reducing the fall time of the output voltage, v_{OUT}, as can be seen in a third plot 113.

Delays in the rise and fall times of the output voltage represent a loss of efficiency. Ideally, v_{OUT} should replicate a step function (i.e. rise and fall quickly) for maximum efficiency.

In FIG. 1A, the electronic switch 103 controls an inductive load 104. Optionally, the inductive load is a motor winding of a Brushless DC (BLDC) machine. Due to the inductive nature of the load 104 and stray parasitic inductances and capacitances of the PCB the drain current, i_{D}, will experience ringing when the electronic switch 103 switches between states. This effect can be seen in a fourth plot 114. The greater the gate current, i_{G}, the quicker the output voltage, v_{OUT}, changes and the larger the amplitude of ringing on the drain current, i_{G}. A varying current flow like this can increase the amount of electromagnetic (EM) radiation from the switching circuit. Consequently, the electronic motor control circuit of FIG. 1A contains a trade-off between achieving high efficiency (e.g. by using a sharp-pulse switching waveform) and remaining compliant with Electromagnetic Compatibility (EMC) regulations by limiting the amount of ringing on the drain current.

Modern GaN and SiC devices can produce ringing with frequency components of hundreds of megahertz. In a motor driver system incorporating feedback to optimize the gate drive waveform, this requires ADCs with GSps rates. At the time of writing, a 1 GSps ADC costs >£100, this price point puts it out of the range of many application.

It was recognized that in a stably operating system output waveforms (I_{D} and/or V_{OUT}) are both repetitive over many cycles, until a change in operating conditions occurs, or there is user input. It was moreover recognized that, in light of this, the shape of the output waveform can be reliably determined by sub-sampling the waveform as described below.

In embodiments the above problem is addressed by sampling an output voltage waveform once every pulse period as shown in FIG. 2, wherein the sample point is acquired at different time points in the various pulse periods, for example in following or adjacent pulse periods. In one embodiment, the sampling points occur at an increasing time increment relative to the start of each pulse. This builds up a representation of the input signal. The shape of the output waveform is then reconstructed by combining the individual sampling points as shown in FIG. 2. The thus reconstructed waveform is used by the active gate driver to pre-distort the driving current i_{G} in a manner that reduces or even eliminates ringing in the output waveform

FIG. 3 illustrates an arrangement in which the output voltage v_{OUT} of an inductive load is sampled using a combination of a fast sample and hold (S/H) gate 301 that is opened for a small (for example, 1 ns) window relative to the pulse duration to charge a capacitor 302 within the sample and hold gate using the voltage v_{OUT}. The sampling duration and frequency of the sample and hold gate 301 as well as the sample frequency of the slower ADC 303 are controlled by a processor 304, as shown in FIG. 4. Sampling with the sample and hold gate 301 with the 1 ns window of the above example is equivalent to a sampling rate of 1 GSps for the S/H gate. The processor 304 operates the S/H gate to samples v_{OUT} at the same rate as the slower ADC 303 converts the sampled voltage into a digital signal. Thus, the processor 304 operates the sample and hold gate 301 and the ADC 303 in a synchronized manner, albeit with the sample and hold gate 301 using varying offsets within the ADC’s clock cycle for sampling. In one example, the slower ADC 303 samples at a relatively low rate of 10 kSps. In an embodiment shown in FIG. 4, the sample and hold circuit 301 samples v_{OUT} at a delay of t₁ relative to a sampling time used in a first ADC clock cycle. During the next pulse period a delay time of 2*t₁ is used, etc until N*t₁ (wherein N is the number of the sampled pulse cycle) is equal to the period of the ADC clock, so that, in this example, the sampling time offset changes linearly. Thereafter, a new cycle is started.

In an alternative embodiment illustrated in FIG. 5, samples are taken at random times relative to the start of the each ADC clock cycle. The times at which such random samples are taken are known to the processor/controller responsible for reconstructing the sampled waveform. These times may, for example, be predetermined/factory set and known to both the processor 304 and, if the controller 305 is configured to reconstruct the waveform then also to controller 305.

The digital signal generated by the ADC 303 is fed back to the controller 305 of the active gate driver, where the individual sampling points are accumulated to form a fully sampled waveform of the output signal (v_{OUT} in this example), for example in the manner illustrated in FIGS. 2 and 5. Alternatively, the processor 304 may be used to assemble the waveform. In this instance, the processor 304 may provide a signal conveying the shape of the waveform to the controller 305.

Basic gate drivers, such as the one shown in FIG. 1, may struggle to simultaneously achieve high efficiency and whilst remaining EMC compliant when driving a switching device. The active gate driver of the embodiment can attain both, by producing a very precisely shaped gate drive waveform. This waveform is precisely generated for one set of operating conditions. Operating conditions include supply voltage, output load current, temperature and aging. Any change in one operating condition will require a different gate waveform. In an embodiment, the output voltage and current at the switching device are sampled as shown in either of FIGS. 2 and 5, where V_{OUT} is sampled as V_{Sample}. Feedback of these sampled signals is used by a controller, which generates the precise gate waveform.

It will be appreciated that, whilst embodiments acquire a single sampling point per pulse period, the advantages described herein are not limited to such configurations. In other embodiments a higher number of sampling points per pulse period may be used. Such other embodiments still achieve the advantages described herein, as long as the number of sampling points is lower than the number of sampling points required to fully characterize the waveform.

While certain arrangements have been described, the arrangements have been presented by way of example only, and are not intended to limit the scope of protection. The inventive concepts described herein may be implemented in a variety of other forms. In addition, various omissions, substitutions and changes to the specific implementations described herein may be made without departing from the scope of protection defined in the following claims.

1. A closed loop active gate driver configured to drive a switch for an inductive load and comprising a feedback loop, the feedback loop configured to sample an output waveform of the inductive load, the output waveform having a plurality of repetitive cycles and the feedback loop configured to sample the output waveform using a sampling rate that is lower than a sampling rate required for characterizing the output waveform, wherein sample points acquired in cycles of the plurality of cycles are acquired at different time points during the cycles and wherein a representation of the output waveform is reconstructed using the sample points.

2. The closed loop active gate driver of claim 1, wherein the feedback loop comprises a sample and hold circuit and the active gate driver further comprises a controller configured to control the sample and hold circuit such that the sample and hold circuit acquires said sample points at the different time points during the cycles and such that a sample period during which the sample and hold circuit samples the output waveform is of a duration that enables the reconstruction of the output waveform using the sample points.

3. The closed loop active gate driver of claim 1, wherein the sample period is of a duration over which a sampled characteristic of the output waveform remains substantially unchanged.

4. The closed loop active gate driver of claim 1, wherein each sample point of the sample points is offset from a start point of a cycle of the plurality of cycles in which the sample point is acquired and where the offset increases from cycle to cycle.

5. The closed loop active gate driver of claim 4, wherein the offset for a next cycle is set to zero if an increase of an offset used in a current cycle is longer than a known or estimated length of the waveform cycle.

6. The closed loop active gate driver of claim 1, wherein each sample point of the sample points is offset from a start point of a cycle of the plurality of cycles in which the sample point is acquired and wherein the offset is random over the cycles.

7. The closed loop active gate driver of claim 1, wherein the switch is a GaN transistor or a SiC Metal Oxide Semiconductor Field Effect Transistor (MOSFET).

8. The closed loop active gate driver of claim 1, further comprising a further switch driven by a further active gate driver, wherein said feedback loop is configured to provide feedback to the active gate driver and to the further active gate driver.

9. The closed loop active gate driver of claim 1, further comprising at least one of a microprocessor or a field programmable gate array, the at least one microprocessor or field programmable gate array configured to reconstruct said output waveform.

10. The closed loop active gate driver of claim 1, wherein the feedback loop comprises a low-speed ADC.

11. A system comprising a motor and the active gate driver of claim 1, wherein said inductive load is at last one winding of the motor and wherein said feedback loop is configured to sample said output waveform at said at least one winding.

12. The system of claim 11, wherein the motor is a brushless DC motor.

13. A method of obtaining a representation of an output waveform of an inductive load driven by a switch the output waveform having a plurality of repetitive cycles, the method comprising:
sampling each cycle of the plurality of repetitive cycles using a sampling rate that is lower than a sampling rate required for characterizing the cycle, wherein sample points acquired in cycles of the plurality of cycles are acquired at different time points during the cycles and
reconstructing a representation of the output waveform using the sample points.

14. The method of claim 13, further comprising providing the representation of the output waveform to an active gate driver connected to the switch.
